(19) United States
(12) Patent Application Publication
(10) Pub. No.: US 2025/0132066 A1
(43) Pub. Date: Apr. 24, 2025

(54) HIGH TEMPERATURE AND LOW PRESSURE SUPERCONDUCTOR

(71) Applicant: University of Rochester, Rochester, NY (US)

(72) Inventor: Liyanagamage R. Dias, Rochester, NY (US)

(73) Assignee: University of Rochester, Rochester, NY (US)

(21) Appl. No.: 18/681,502

(22) PCT Filed: Jul. 26, 2022
(86) PCT No.: PCT/US2022/038408

§ 371 Date: Feb. 5, 2024

Related U.S. Application Data
(60) Provisional application No. 63/230,669, filed on Aug. 6, 2021.

(51) Int. Cl. H01B 1/06; H01B 12/00

(52) U.S. Cl. CPC H01B 1/06; H01B 12/00

(57) ABSTRACT

Materials are disclosed that superconduct at high temperatures and low pressures. Methods of making and measuring the materials are also disclosed. In a particular embodiment, a nitrogen-doped (or other lightweight-atom doped) rare earth metal hydride is disclosed. Also disclosed are thermodynamic pathways to recovering materials that superconduct at room temperature and room pressure and/or at other desirable operating temperatures and pressures to enable superconductivity at conditions that make a wider range of superconductive applications practical. These and other aspects of various embodiments are disclosed herein.

### CROSS-REFERENCE TO RELATED APPLICATIONS

This application claims the benefit of U.S. Provisional Application Ser. No. 63/230,669 filed on Aug. 6, 2021. The entire contents of that application are hereby incorporated by reference herein.

### STATEMENT REGARDING FEDERALLY SPONSORED RESEARCH

This work was done with government support under Grant No. DMR-2046796 awarded by the National Science Foundation. The government has certain rights in the invention.

### BACKGROUND

The present disclosure relates to superconducting compositions of matter and methods of making the same.

Superconductivity has been known for over 100 years. However, materials developed to date do not exhibit superconductivity at ambient conditions that are sufficiently close to those necessary for many practical applications. Developing materials that can exhibit superconductivity at commercially viable temperature and pressure conditions is necessary to leverage the significant potential benefits of superconductivity on a larger scale.

### SUMMARY

The search, synthesis, and structural and physical characterization of novel materials with high superconducting transition temperatures needed for observation of room temperature superconductivity (RTSC), and an understanding of how to access metastable pathways to their recovery to ambient conditions, is important for advancing material science and energy transmission technology. Limitations with the energy storage produced from renewable energy technologies can be overcome with superconductors providing an extremely efficient means of storing and recovering energy on demand, as well as a method for transferring energy over long distances. A robust superconductor, suitable for the construction of Josephson junction quantum logic gates that can operate at higher temperatures has the potential to provide a revolutionary new switching mechanism for computing.

Higher temperature conventional superconductivity in hydrogen-rich materials has been reported in several systems under high pressure. See, Drozdov, A. P., Eremets, M. I., Troyan, I. A., Ksenofontov, V. & Shylin, S. I. Conventional superconductivity at 203 kelvin at high pressures in the sulfur hydride system, Nature 525, 73-76 (2015); Drozdov, A. P. et al. Superconductivity at 250 K in lanthanum hydride under high pressures, Nature 569, 528-531 (2019); and Somayazulu, M. et al. Evidence for Superconductivity above 260 K in Lanthanum Superhydride at Megabar Pressures, Phys. Rev. Lett. 122, 27001 (2019). However, these materials previously identified and made do not exhibit superconductivity at a combination of pressures and temperatures needed for most commercial applications. More recently, even higher temperature, including room-temperature conductivity was reported in a carbonaceous sulfur hydride system, also under high pressure. See, Snider, E., Dasenbrock-Gammon, N., McBride, R. et al. (including Dias, R.) Room-temperature superconductivity in a carbonaceous sulfur hydride, Nature 586, 373-377 (2020).

However, for many potentially useful applications of superconductivity to be further realized in a practical and scalable way, it is important to develop materials that can exhibit and sustain superconductivity not only at near room temperature conditions, but also at lower pressures, closer to the atmospheric pressure found in our daily lives.

Embodiments of the present invention address this need by providing materials and corresponding methods of making those materials that demonstrate superconductivity at room temperature or near room temperature with pressure levels far lower than found in the prior art. Notably, in one embodiment, the disclosed material exhibits superconductivity at room temperature and room pressure, a combination of conditions that represents an unprecedented advance in superconducting technology.

Additional embodiments also provide inventive methods and apparatuses for effectively measuring magnetic susceptibility and heat capacity under high pressure in a diamond anvil cell (DAC). Both of these material characteristics provide evidence of superconductivity and therefore these embodiments provide important tools in the search for new superconductive materials. However, these characteristics have previously been difficult if not impossible to measure in a high pressure DAC context.

### BRIEF DESCRIPTION OF THE DRAWINGS

FIG. 1 is a flow diagram illustrating a method of making a nitrogen-doped lutetium hydride superconductor. The method and the resulting material are consistent with present embodiments of the invention.

FIG. 2 is a flow diagram illustrating a method for further thermodynamic processing of a material that is superconducting under pressure to obtain a material exhibiting superconductivity at room temperature and room pressure conditions. The method and the material are consistent with embodiments of the present invention.

FIGS. 3A-3D are images of a material embodying the invention before and after implementing the last step of the method of FIG. 1.

FIG. 4 presents data confirming the superconductivity of a material embodying the invention, including one made according to the process of FIG. 1.

FIG. 5A-5B present data from testing the material's superconductivity at room pressure using resistance measurements.

FIG. 6 illustrates the crystal lattice structure of a unit cell of a composition of matter embodying the invention.

FIG. 7 shows the volume as a function of pressure, of a material in accordance with an embodiment of the invention.

FIG. 8 presents energy dispersive x-ray (EDX) measurements of a material in accordance with an embodiment of the invention.

FIG. 9 shows Rietveld refinement of X-ray dispersion (XRD) data collected at 295 K with Cu-Kα radiation with refining the occupancy of the tetrahedral interstitial site with N for LuH_{3-d}Nₑ, the material being in accordance with an embodiment of the invention.

FIG. 10 presents simulated data of the XRD pattern with Cu-Kα wavelength for LuH₃; LuH_{3-δ}N_{ε} replacing a single H with an N in an octahedral site; and LuH_{3-δ}N_{ε} replacing a single H with an N in a tetrahedral site. Distinctions between the three materials exist in the simulated data but are not clearly shown in FIG. 10.

FIG. 11A presents a closer view of the simulated data shown in FIG. 10 near the peak associated with the (111) plane. It shows some distinction between LuH_{3-δ}N_{ε} with an N-for-H substitution at a tetrahedral site (green line) versus at an octahedral site (blue line).

FIG. 11B presents a closer view of the simulated data shown in FIG. 10 near the peak associated with the (200) plane. It shows some distinction near the peak between LuH₃ (red line), LuH_{3-δ}N_{ε} with an N-for-H substitution at a tetrahedral site (green line), and LuH_{3-δ}N_{ε} with an N-for-H substitution at an octahedral site (blue line).

FIG. 12 shows the spectral deconvolution of Raman spectra of the LuH_{3-δ}N_{ε} compound upon compression.

FIG. 13 shows the Raman shift vs pressure of the sample.

FIG. 14 illustrates an internal side view of a membrane-driven diamond anvil cell (DAC) setup used to compress samples of the disclosed material and measure properties associated with superconductivity under various pressures and temperatures.

FIGS. 15A and 15B illustrate placement of diamond powder in a gasket's indentation and hole in the setup of FIG. 14.

FIGS. 16A-16B illustrate a setup for obtaining resistance measurements of a sample under pressure in the DAC.

FIG. 17 is an image of an actual setup from a perspective similar to that illustrated in FIG. 16B.

FIG. 18 presents data for a material embodying the invention of resistance versus temperature for three different pressures.

FIG. 19 illustrates an internal top view of an experimental setup for measuring magnetic susceptibility within a DAC, in accordance with one embodiment of the invention.

FIG. 20 illustrates a side view of the same setup shown in FIG. 19.

FIG. 21 is a photograph of a susceptibility measurement setup consistent with the internal top view schematic of FIG. 19.

FIG. 22 presents data showing the real part of A.C. magnetic susceptibility (c′) in nanovolts (nV) versus temperature at three different pressures with respect to a material embodying the invention.

FIG. 23 present data showing the magnetic susceptibility (c′=M/H, where M is magnetization and H is magnetic field) of the sample as a function of temperature, under conditions of zero field cooling (ZFC) and field cooling (FC) at 25 Oe.

FIG. 24 shows an example of A.C. susceptibility versus temperature data obtained at various pressures using larger samples.

FIG. 25 illustrates an internal top view of an experimental setup for measuring heat capacity within a DAC, in accordance with one embodiment of the invention.

FIGS. 26A-26B are images of an actual setup corresponding to the schematic illustration of FIG. 25.

FIGS. 27A-27D show specific heat measurements versus temperature at various pressures using the experimental setup described above.

FIG. 28 shows specific heat measurements versus temperature taken at 26 kbar. The inset shows the frequency sweep done in advance to identify the preferred drive frequency.

While the invention is described with reference to the above drawings, the drawings are intended to be illustrative, and other embodiments are consistent with the spirit, and within the scope, of the invention.

### DETAILED DESCRIPTION

Embodiments of the disclosure include materials exhibiting superconductivity at unprecedented combinations of high temperatures and low pressures. Embodiments further include various methods for making such materials. Embodiments further include thermodynamic processing of superconducting materials to recover stable or metastable materials that exhibit superconductivity at or near typical room temperatures and pressures. Additional embodiments enable measurement of magnetic susceptibility and heat capacity in the challenging environment of a high pressure diamond anvil cell (DAC).

### Making Superconducting Material Embodiments

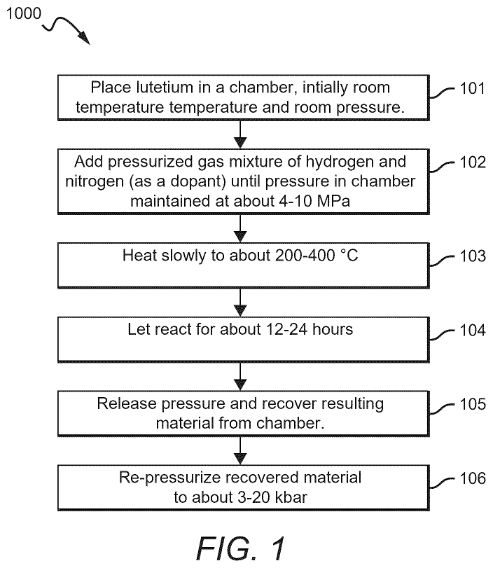

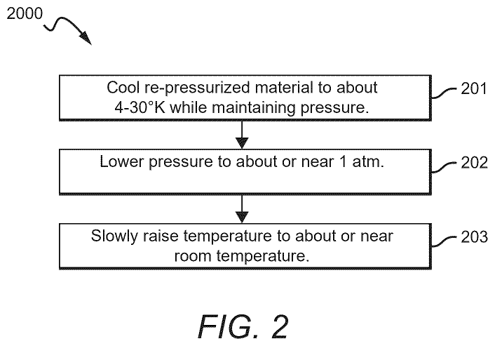

FIG. 1 is a flow diagram illustrating a method 1000 used to make a nitrogen-doped lutetium hydride embodiment of the inventive composition of matter for which results are disclosed herein. The details disclosed for method 1000 are disclosed to enable one skilled in the art to make embodiments of the composition of matter disclosed herein. However, those skilled in the art will appreciate that embodiments of the disclosed composition of matter can be made using steps and parameters that vary from the exact method disclosed in the context of FIG. 1 and/or FIG. 2.

Regarding to FIG. 1, at step 101, a rare earth metal (Ln) such as lutetium (Lu) is placed in a pressure chamber. In one embodiment, the Lu has purity of at least 99%. In another embodiment, the metal element has purity of at least 99.9%. In another embodiment, the metal element has purity of at least 99.99%. In one embodiment, the pressure is initially at or near room pressure.

At step 102, a pressurized mixture of hydrogen gas (H₂) and a dopant such as nitrogen gas (N₂) are added to the chamber. In one embodiment, substantially more hydrogen than nitrogen is added. In a particular embodiment, hydrogen and nitrogen are added in a molecular weight ratio of about 99:1. In a particular embodiment the amount of hydrogen relative to nitrogen is more than 99:1. In various other respective embodiments, the amount of hydrogen relative to nitrogen is about or more than a respective one of the following ratios: 9:1, 91:9, 92:8, 93:7, 94:6, 95:5, 96:4, 97:3, 98:2, or 99:1. In the illustrated embodiment, the pressurized gas is added until the pressure in the chamber is in the range of about 4-10 megapascals (MPa).

At step 103, with the pressure maintained at about 4-10 MPa, the chamber is slowly heated (e.g., at about 1 kelvin (K) per minute) until the temperature is about 200-400 degrees Celsius (° C.).

At step 104, with the above-referenced temperature and pressure maintained, the material is left in the chamber to react for about 12-24 hours until an fcc material is formed.

At step 105, the chamber is allowed to cool to room temperature and the pressure is released. The material, which at this point is blue in color, can be recovered from the chamber.

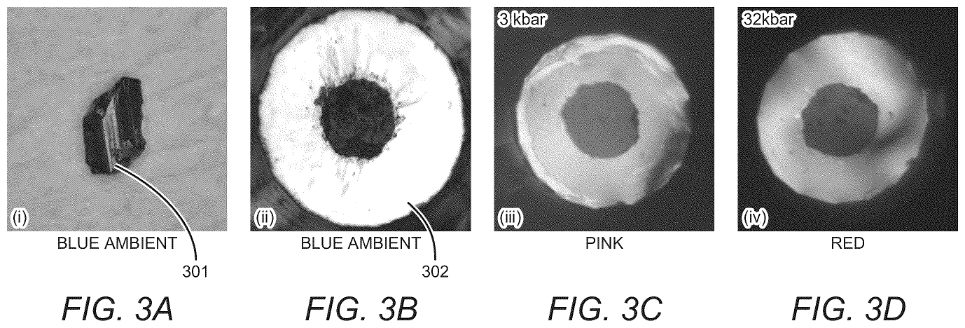

At step 106, the recovered material is repressurized to about 3-20 kilobar (kbar). In one embodiment, before being repressurized, the material is ball-milled into a fine powder using one or more 3 mm zirconia grinding balls. As will be discussed further in the context of FIG. 3, in one example, the repressurized material of step 106 exhibits a high critical temperature (Tc) (the temperature at or below which the material is superconductive) over a wide range of pressures. In one example, the material's Tc is near or at room temperature (e.g., 290 K, 293 K, 294 K, etc.) over a range of pressures around 10 kbar (e.g., about 8-12 kbar, about 7-13 kbar, etc.). In one embodiment, the reactions resulting from these steps can be summarized as follows:

Lu+H₂+N₂→LuHₓN_{y}+H₂+N₂→LuH_{3-δ}N_{ε}

In one alternative embodiment, step 105 is omitted and, instead of releasing the pressure and recovering the material, the pressure is simply increased from 4-10 MPa to 3-20 kbar. However, in the embodiment shown in FIG. 1 (that includes step 105), recovering the material at room pressure prior to re-pressurizing allows the presence of the fcc structure to be verified via X-ray diffraction.

In some alternative embodiments, the method illustrated in FIG. 1 is modified as follows: The metal gas mixture is first allowed to react for several hours at lower pressure, for example, in the range of about 10-30 kbar until an hcp material is formed. Then, the hcp material is further pressurized to a higher pressure (in the gigapascal range rather than in the MPa range) of about 12-17 gigapascals (GPa). The chamber is slowly heated to 200-400° C., and then the hcp material and the gas mixture are allowed to further react for 12-24 hours until an fcc material is formed. The method then proceeds in the same manner illustrated in steps 105-106 of FIG. 1.

As discussed further below in the context of various figures, the repressurized material obtained at step 106 exhibits high temperature superconductivity over a significantly lower pressure range than found in previous hydride compounds. But the importance and breakthrough nature of the present disclosure is even further demonstrated by additional thermodynamic processing of the material that allows recovery of a stable or metastable superconducting material at or near room temperature and at or near room pressure (i.e., typical ambient atmospheric pressure), as will now be described in the context of FIG. 2.

FIG. 2 is a flow diagram illustrating a method 2000 for further thermodynamic processing of a material such as, for example, a material resulting from method 1000 to obtain a material exhibiting superconductivity at room temperature and room pressure conditions.

Although the cooling and pressure parameters referenced in FIG. 2 are described in the context of LuH_{3-δ}N_{ε}, the broader principles of the disclosed thermodynamic processing pathway can be stated and applied more generally. In its broadest aspects, the disclosed pathway involves the following steps. First, obtaining a material at a first higher pressure that superconducts at that first higher pressure and at a desirable practical operating temperature (e.g., room temperature). Next, while maintaining the material at the first higher pressure, cooling it to a very low temperature. Next, releasing the pressure to a second, lower pressure (e.g., room pressure) and then slowly raising the temperature (e.g., at about 1 K per minute) to a higher temperature such as the desirable practical operating temperature (e.g., room temperature).

In other words, these principles apply to a material that is shown to superconduct under a first higher pressure and at a desirable operating temperature (e.g., room temperature or some other temperature acceptable for widespread practical applications). The disclosed technique allows one to take such a material and obtain a new version of that material that not only superconducts at the desirable operating temperature and first higher pressure, but that also superconducts at the desirable operating temperature AND at a significantly lower second pressure desirable for practical applications (e.g., room pressure). Various alternative temperature and pressure parameters are disclosed below consistent with application of this technique to LuH_{3-δ}N_{ε} and to other materials.

At step 201, the repressurized material is maintained at a pressure in a range of about 3-20 kbar and then cooled to about 4-30 K. In one embodiment, it is maintained at a pressure in a range of about 3-10 kbar. In another embodiment, it is maintained at a pressure in a range of about 8-12 kbar. In other embodiments, which may involve one of various other materials, it is maintained at whatever pressure the relevant material was found to exhibit room-temperature (or near room-temperature) superconductivity. In one embodiment, it is cooled to a temperature in the range of about 3-30 K. In another embodiment, it is cooled to a temperature in the range of about 10-25 K. In another embodiment, it is cooled to a temperature in the range of about 15-20 K. In another embodiment, it is cooled to a temperature in the range of about 31-40 K. In another embodiment, it is cooled to a temperature in the range of about 41-50 K. In another embodiment, it is cooled to a temperature in the range of about 51-60 K. In another embodiment, it is cooled to a temperature in the range of about 61-70 K. In another embodiment, it is cooled to a temperature in the range of about 71-80 K. In another embodiment, it is cooled to a temperature in the range of about 81-90 K. In another embodiment, it is cooled to a temperature in the range of about 91-100 K. As one skilled in the art would understand, different combinations of pressures and temperatures might be best suited to apply the illustrated process to different materials.

At step 202, a low temperature is maintained while the pressure is released and lowered to about or near room pressure (e.g., about 1 atmosphere). At step 203, the temperature is allowed to naturally rise (e.g., at about 0.2 K per minute) to at or near room temperature.

In one embodiment, the resulting material has a Tc of at least 250 K at room pressure. In another embodiment, the resulting material has a Tc of at least 290 K at room pressure. In another embodiment, the resulting material has a Tc of at least 294 K at room pressure. In another embodiment, the resulting material has a Tc of at least 294 K at a pressure between about 10-100 bar. In another embodiment, the resulting material has a Tc of at least 300 K at a pressure between about 100-500 bar.

FIGS. 3A-3D are images of the material before and after implementing step 106 of method 1000. FIG. 3A shows material 301 recovered from a reaction chamber at room pressure and temperature after step 105 of method 1000 of FIG. 1. The material is a lustrous blue color. FIG. 3B shows material 301 after it has been ground into powder and placed into a gasket 302 in which the material will be re-pressurized using a diamond anvil cell (DAC). In FIG. 3B, the material is still at room pressure and room temperature and still has a blue color. FIG. 3C shows the material under pressure of 3 kbar, having turned pink in color. FIG. 3D shows the material under pressure of 32 kbar, having turned red in color.

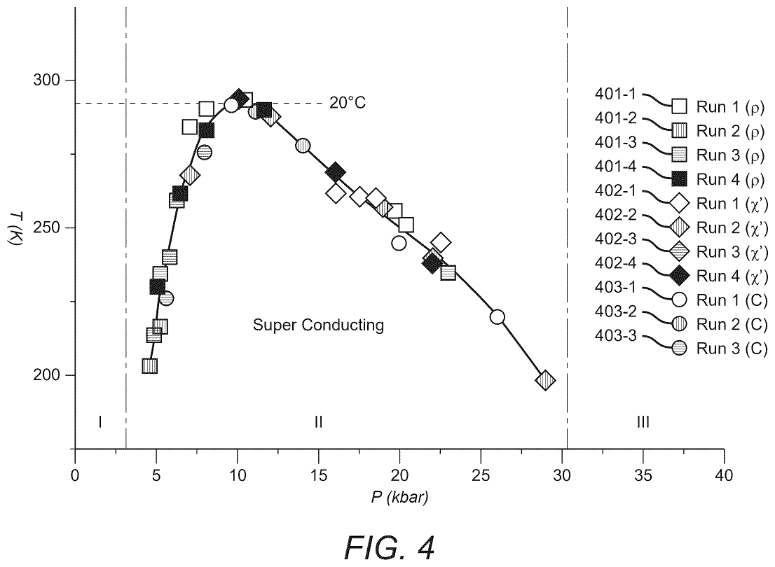

FIG. 4 presents data confirming the superconductivity of the material made according to process 1000 of FIG. 1. Superconductivity is confirmed using three different types of measurements with remarkable consistency at an unprecedented combination of high temperatures and sub-megabar pressures. FIG. 4 presents superconductivity Tc and pressure data obtained using the following different types of measurements to confirm the transition to superconductivity: resistance (represented by squares 401-1, 401-2, 401-3, and 401-4 for corresponding respective experiment runs), magnetic susceptibility (represented by diamonds 402-1, 402-2, 402-3, 402-4 for corresponding respective experiment runs), and heat capacity (represented by circles 403-1, 403-2, and 403-3 for corresponding respective experiment runs).

As illustrated, the data in FIG. 4 shows high temperature superconductivity of the material from about 3-30 kbar, with a highest Tc around 294 at around 10 kbar. As pressure increases past 10 kbar, Tc begins dropping and, above 30 kbar, the data shows the material no longer exhibiting superconductivity at temperatures above 200 K.

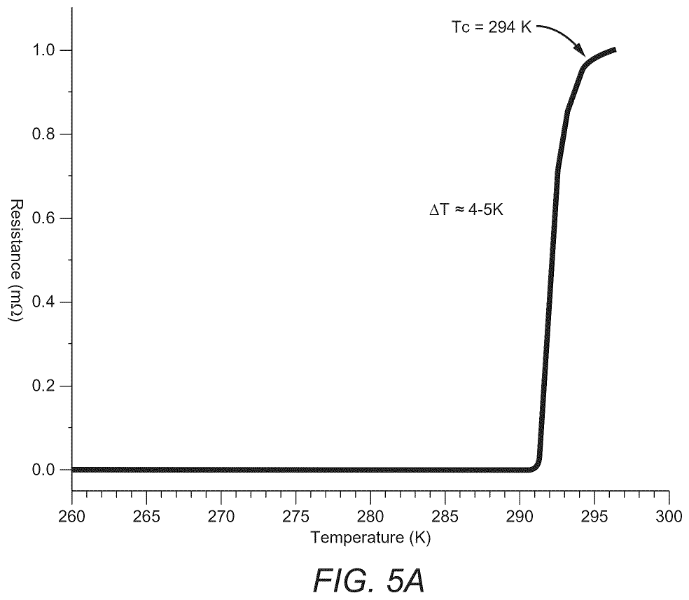

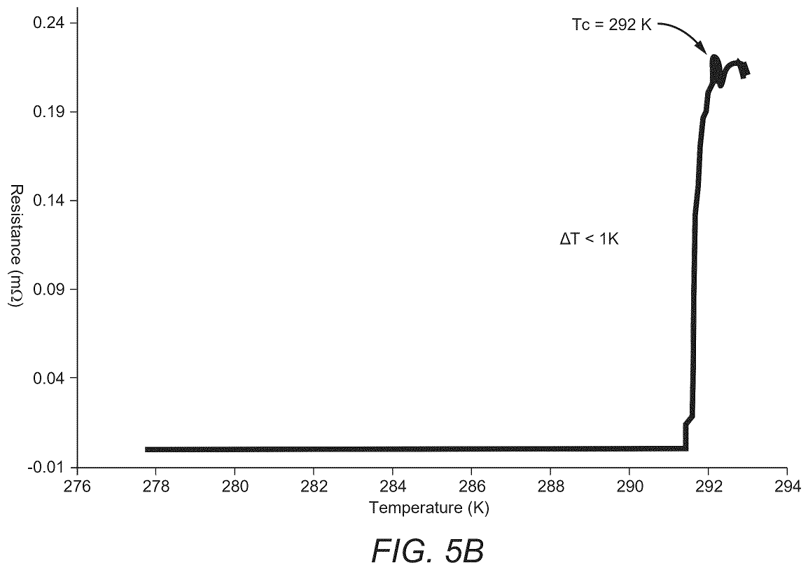

FIG. 5A-5B present data from testing the material's superconductivity at room pressure using resistance measurements. The data of FIGS. 5A-5B was obtained by testing samples of the material that had undergone the further thermodynamic processing of method 2000 illustrated in FIG. 2, which was done after repressurizing the material in step 106 of method 1000 of FIG. 1.

The room temperature and room pressure superconductivity demonstrated for the material resulting from implementing method 200 on the material obtained from method 100 is a breakthrough advance in superconductor technology. The extremely low temperature and/or high pressure requirements of previous superconductive materials placed significant obstacles on their use in most practical applications. However, the presently disclosed material leaps past those obstacles and provides the first known room temperature, room pressure superconductor.

FIG. 5A presents data of a first sample tested at room pressure conditions. The width of the superconducting transition shown is about 4-5 K. The sample showed a Tc of 294 K (i.e., about 69° F. and nearly 21° C.). In other words, the material is superconductive at typical ambient temperatures and pressures found in our daily lives.

FIG. 5B presents data of a second sample tested at room pressure conditions. The sample showed a Tc of about 292 K. The width of the superconducting transition shown is less than 1 K.

### The Material

In a tested example, the bulk material recoverable at room temperature and room pressure conditions after executing step 105 of method 1000 in FIG. 1 is a lutetium-nitrogen-hydrogen compound. Samples analyzed using energy dispersion X-ray (EDX) and Raman spectroscopy show two distinct hydride compounds, both having an fcc metal sub-lattice. One of the two compounds is superconducting.

In an embodiment, the superconducting material is indexed as Fm3̅m. In an embodiment, the stoichiometry of the superconducting compound is given as LuH_{3-δ}N_{ε}, both δ and ε being less than 1. The different variables reflect the possibility of both N substitutions and H vacancy defects in the interstitial sites. In some embodiments, 0≤δ≤0.5 and 0≤ε≤0.3. In some embodiments, δ is about 0.3. In some embodiments, ε is about 0.1. In one embodiment, δ is 2.7 and ε is 0.1. In one embodiment, δ is 0.3 and ε is 0.1. These specific values show examples within the expected ranges of 0≤δ≤0.5 and 0≤ε≤0.3. However, other specific values in those ranges are reasonable.

The composition of the superconducting compound was determined as follows: Energy Dispersive X-ray (EDX) identified Lu, H, and N as consistently present in analyzed samples of the synthesized material, with N being, on average, about 0.8-0.9% of the weight. Raman spectroscopy also confirmed the presence of N in addition to Lu and H in the bulk material. X-ray diffraction (XRD) analysis determined that the compound has an Fm3̅m crystal structure and an observed lattice constant of a=5.02891+/−0.00004 Å. Density functional Theory (DFT) optimizations were then used to model various possibilities to find a composition stoichiometry consistent with the experimental data.

DFT modeling of pure LuH₂ without any N substitution shows a closer match (a=5.025 Å) to the XRD data than does DFT modeling of pure LuH₃ (a=5.012). However, when considering the presence of N in the superconducting material (as indicated by the EDX data), a stoichiometry that assumes N substitutions in interstitial sites relative to pure LuH₃ is a better match for the data than are systems that assume N substitutions relative to pure LuH₂. For example, relative to an LuH₃ structure, DFT modeling based on a single N-for-H a substitution an octahedral interstitial site indicates a=5.028 Å. For a single N-for-H substitution at a tetrahedral interstitial site, it indicates a=5.148 Å. Because the experimental data is consistent with a range of combinations of N substitutions and H vacancy defects at interstitial sites relative to LuH₃, the stoichiometry of the superconducting compound is given as LuH_{3-δ}N_{ε}, (both δ and ε being less than 1).

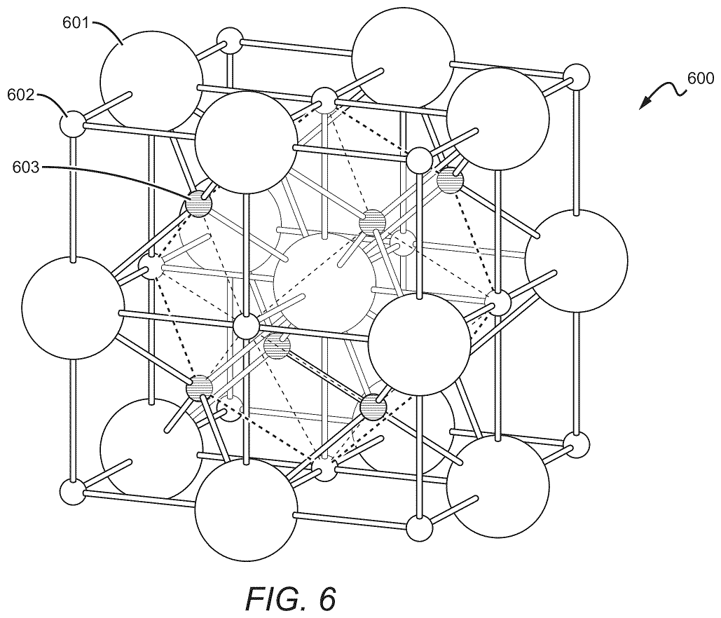

FIG. 6 illustrates the crystal lattice structure of a unit cell 600 of a composition of matter embodying the invention. Unit cell 600 comprises Lu atoms 601 (shown in green) forming an fcc metal sub-lattice. H atoms 602 (shown in white) occupy octahedral interstitial sites and H atoms 603 (shown in pink) occupy tetrahedral interstitial sites. The shaded area highlights the coordination polyhedron. To better illustrate the coordination polyhedron, the unit cell 600 is shown shifted by (0.5, 0.5, 0.5) from the standard view.

Although the illustration shows only H atoms at the interstitial sites, in particular samples, as discussed above, N atoms will be substituted for H atoms at either a tetrahedral or an octahedral interstitial site. As also discussed above, samples of the material embodiments might have H vacancy defects at some of the interstitial sites rather than N substitutions or a combination of both N substitutions and H vacancy defects.

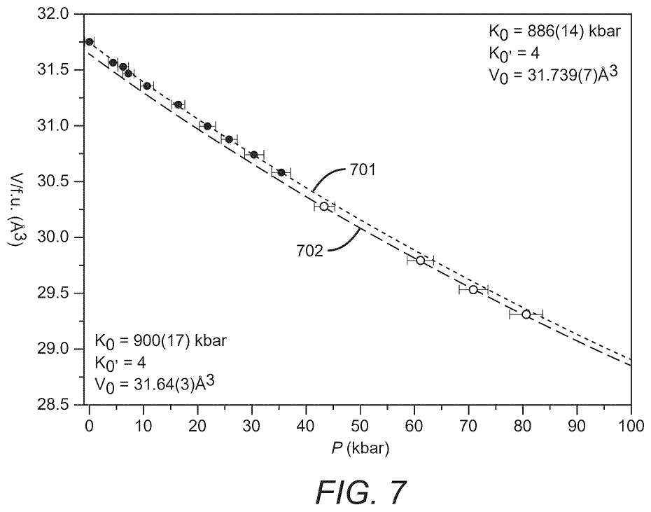

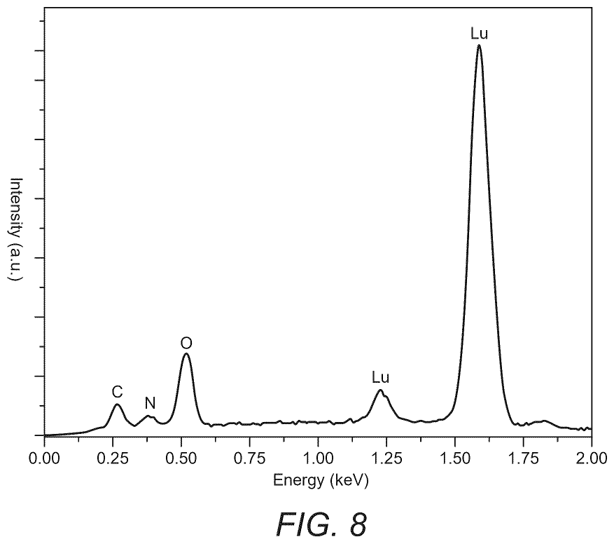

FIG. 7 shows the equation of state, i.e., the volume as a function of pressure, for an embodiment of the superconducting material LuH_{3-δ}N_{ε}. The Le Bail method was used to refine the high pressure XRD data. The equation of state line was fitted using the Birch-Murnaghan method over two pressure ranges: 0<P<40 kbar and P>42.7 kbar. Using data points in the lower pressure range to find the fitted line 701 results in a room pressure bulk modulus (K₀) of 886+/−14 kbar and dK/dP of 4. Using data points in the higher pressure range to find the fitted line 702 results in a room pressure bulk modulus (K₀) of 900+/−17 kbar and dK/dP of 4.

FIG. 8 presents energy dispersive x-ray (EDX) measurements of the material. For these measurements, samples were prepared by mounting on an aluminum pin mount with double sided carbon tape. The samples were then imaged using a Zeiss-Auriga Scanning Electron Microscope (SEM). Regions of interest were chosen by comparing the SEM image to a white light image taken before. EDX measurements were performed within the Zeiss-Auriga SEM with a driving energy of 15 kV and collected and analyzed using an EDAX detector with the EDAX APEX software. Carbon and aluminum peaks seen in the EDX spectra come from the carbon tape and aluminum mount required to place the samples into the SEM vacuum chamber. EDX measurements provide additional evidence for the presence of nitrogen in the samples.

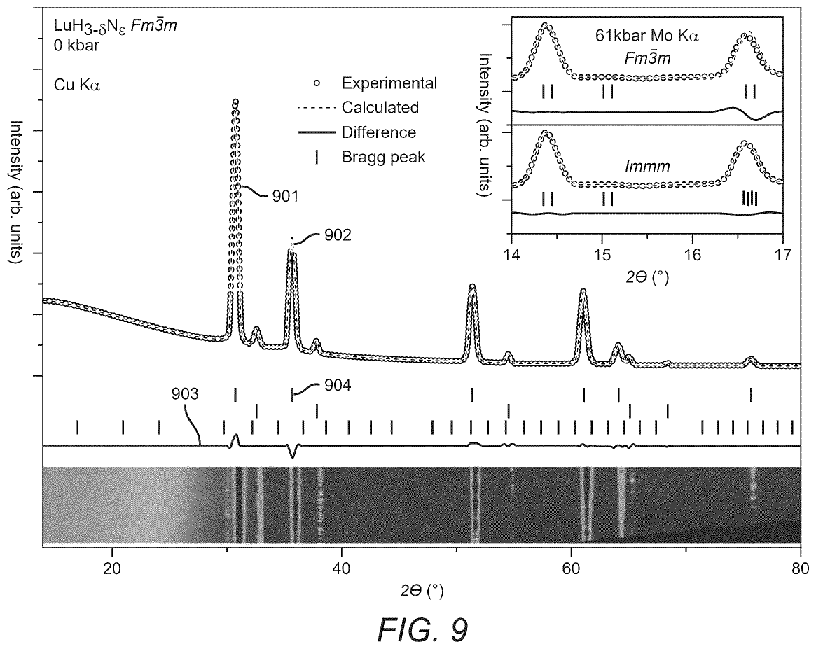

FIG. 9 shows Rietveld refinement of the XRD data collected at 295 K with Cu-Kα radiation with refining the occupancy of the tetrahedral interstitial site with N for LuH_{3-d}Nₑ. The black points, red line and blue line represent the observed data, calculated intensity, and the difference between observed and calculated intensities, respectively. Green tick marks represent the expected Bragg peak positions for the main phase LuH_{3-d}Nₑ (92.25%), minor phases LuH (7.29%) and M₂O₃ (0.46%). The color map shows a cake representation of the XRD data at ambient pressure. The inset shows Le Bail fitting of high pressure powder diffraction data at 61 kbar with Fm3̅m and Immm space groups.

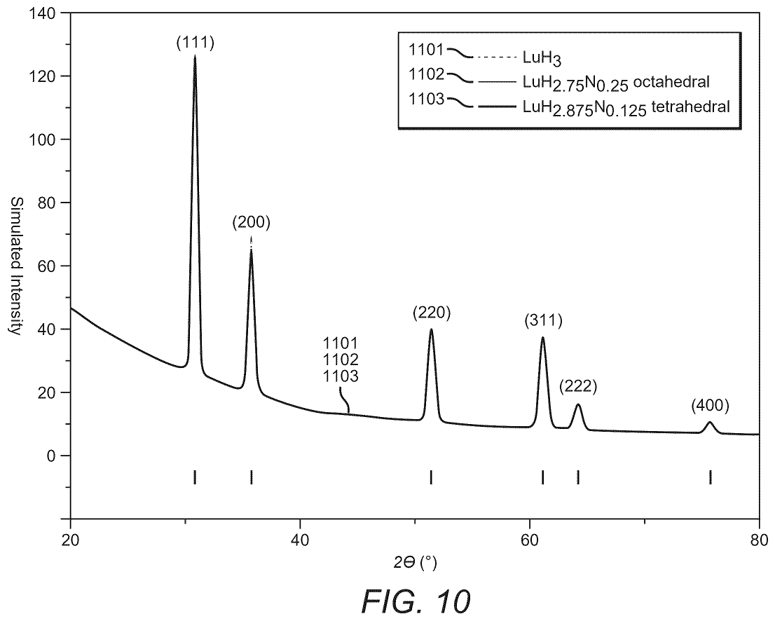

FIG. 10 presents simulated data of the XRD pattern with Cu-Kα wavelength for LuH₃ (red line 1101), LuH_{3-δ}N_{ε} replacing a single H with an N in an octahedral site (blue line 1102) and LuH_{3-δ}N_{ε} replacing a single H with an N in a tetrahedral site (green line 1103). Distinctions between the three materials exist in the simulated data but are not clearly shown in FIG. 10.

Rietveld refinement of the X-ray powder diffraction data of ground powder sample were performed to investigate the possible N substitutions in LuH_{3-δ}N_{ε}. We note here that the X-ray diffraction is mostly dominated by heavy Lu atoms. The refinements of several samples gave positive site occupancies for N with ε in the range of 0.12 to 0.25, which corresponds to 1 to 2 atoms replacement out of 8 atoms in the tetrahedral interstitial site. The refinement shown in FIG. 9 improved the residual factors (Rₚ from 6.97 to 5.73, R_{wp} from 5.75 to 3.80) with this substitution.

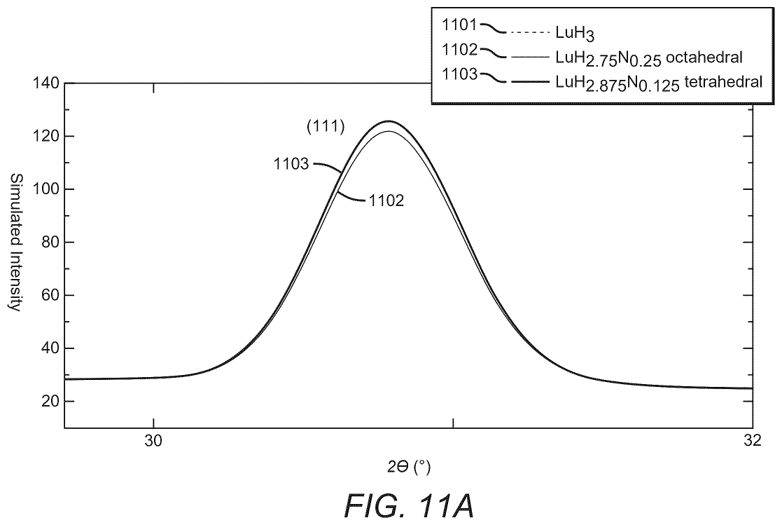

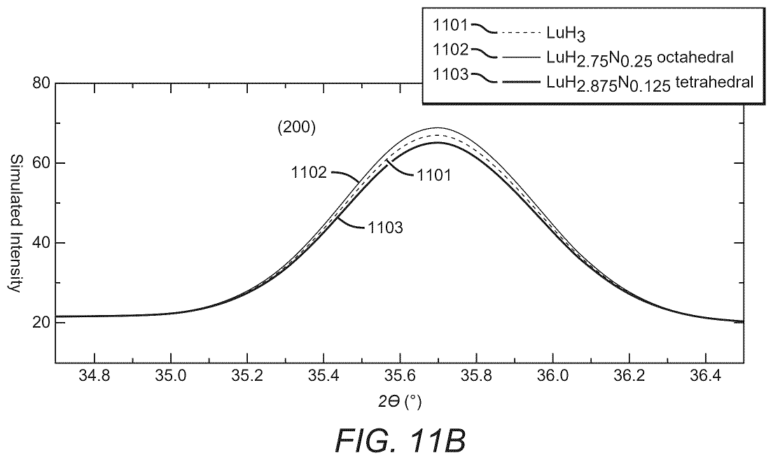

FIG. 11A presents a closer view of the simulated data shown in FIG. 10 near the peak associated with the (111) plane. It shows some distinction between LuH_{3-δ}N_{ε} with an N-for-H substitution at a tetrahedral site (green line 1103) versus at an octahedral site (blue line 1102).

FIG. 11B presents a closer view of the simulated data shown in FIG. 10 near the peak associated with the (200) plane. It shows some distinction between LuH₃ (red line 1101), LuH_{3-δ}N_{ε} with an N-for-H substitution at a tetrahedral site (green line 1103), and LuH_{3-δ}N_{ε} with an N-for-H substitution at an octahedral site (blue line 1102).

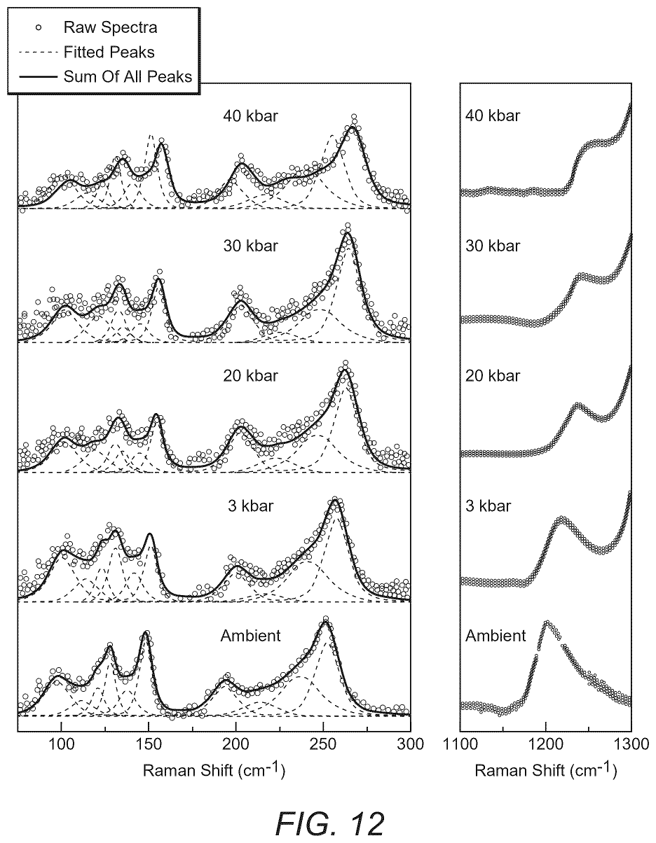

FIG. 12 shows the spectral deconvolution of Raman spectra of the LuH_{3-d}Nₑ compound upon compression.

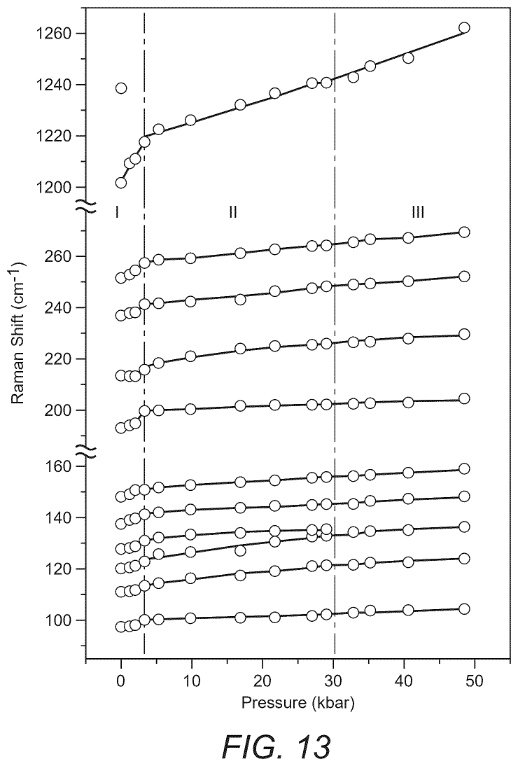

FIG. 13 shows the Raman shift vs pressure of the sample. The dashed lines mark transitions between the three phases observed as pressure increases.

### Alternative/Additional Materials and Methods

In some embodiments, other rare earth elements such as thulium (Tm) or Ytterbium (Yb) are used in place of lutetium (Lu). In some embodiments, boron (B) is used as a dopant instead of nitrogen.

When boron is used, the method of FIG. 1 is, in one embodiment, modified as follows: At step 102, pure hydrogen gas is used instead of a hydrogen-nitrogen mix. Two steps are added between steps 105 and 106. In this modification, the material recovered from the chamber at step 105 is LuH₃. The next step is to ball mill the LuH₃ (or another lanthanide hydride such as, e.g., YbH₃, TmH₃, or DyH₃) together with boron or boron powder. In one embodiment, the ration of H to B is 99:1 by molecular weight. In other embodiment, the ratio is in the range of about 9:1 to 99.9:0.1. Next, the powdered mixture of LuH₃ and B is pressurized to about 4-10 MPa and heated to about 200-500° C. and allowed to react for 24-48 hours forming LnH_{3-δ}B_{ε}. After the newly formed compound cools, then step 106 is performed in a similar manner as it was for LuH_{3-δ}N_{ε} in FIG. 1. In other words, the resulting material is pressurized to about 3-12 kbar.

In some embodiments, large quantities of a disclosed superconducting material is made using molecular-beam epitaxy (MBE) or other methods. Specifically, in one embodiment, a material disclosed herein is used as a substrate to grow additional superconducting material via chemical vapor deposition, atomic layer deposition, or MBE. In another embodiment, a crystal substrate is provided having lattice parameters that will impart a strain on a first layer of superconducting material disclosed herein and deposited on the substrate via MBE. The strain is sufficient to reduce the ambient pressure at which the material is superconducting at room temperature or at other temperatures above 250 K, above 290 K, or above 300 K. Techniques for such strain engineering to grow superconductive material via MBE are disclosed in International Application Number PCT/US2021/043785, published as WO 2022/055628 A2, the entire contents of which are hereby incorporated by reference.

### Diamond Anvil Cell Superconductivity Measurements

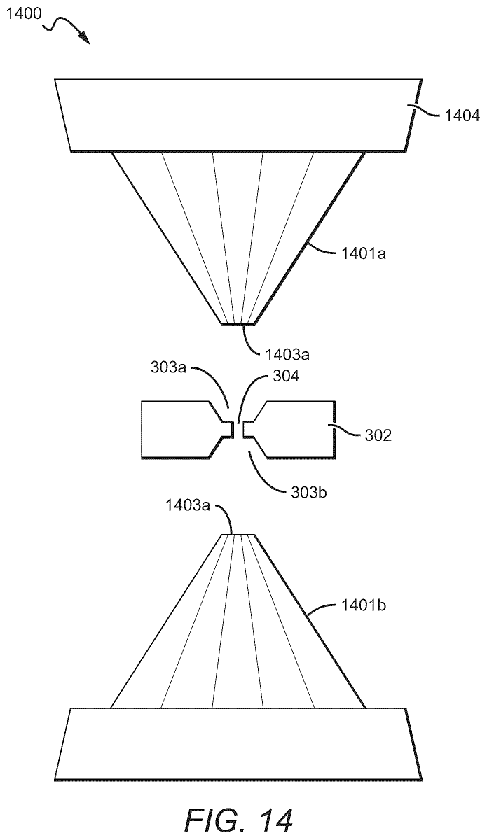

FIG. 14 illustrates an internal side view of a membrane-driven diamond anvil cell (DAC) setup 1400 used to compress samples of the disclosed material and measure properties associated with superconductivity under various pressures and temperatures. The data presented herein is based on experiments conducted on more than fifty samples.

DAC setup 1400 comprises top diamond 1401a, bottom diamond 1401b, which are each mounted in a tungsten carbide base 1404. Top diamond 1401a has a culet 1403a and bottom diamond 1401b has a culet 1403b. In experiments investigating the presently disclosed material, ⅓ carat type la diamonds with various size culets were used (smaller for high pressure, larger for lower pressure) including 0.2, 0.4, 0.6, and 0.8 mm.

Rhenium gasket 302 is pre-indented with the diamond anvils to provide indentations 303a and 303b. The size of the indentation varies depending on the pressure level to be applied. In the disclosed experiments, the size varies between 15-25 μm. A hole 304 is drilled through the center of the indentation. In this example, the hole was either 120, 280, or 600 um depending on the pressure to be applied. Hole 304 provides the sample chamber.

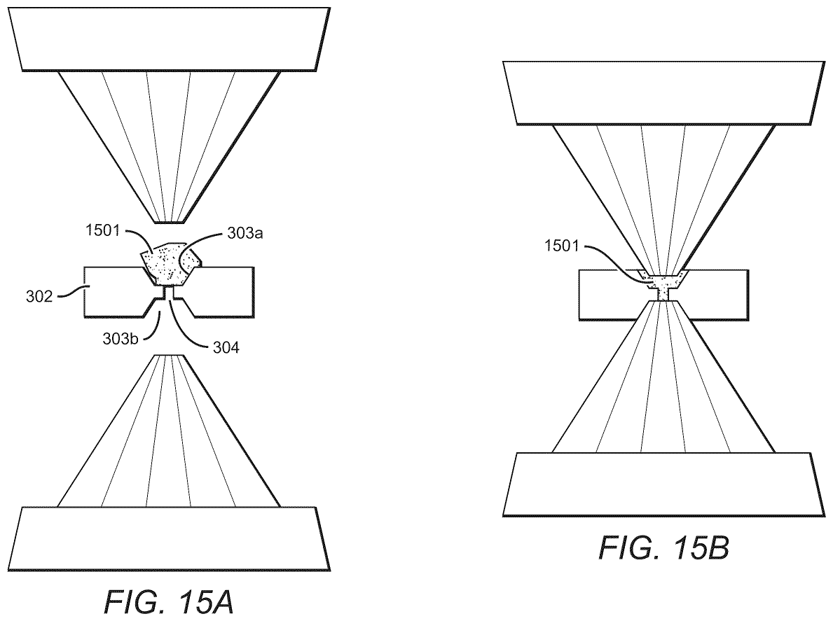

FIG. 15A illustrates diamond powder 1501 placed in indentation 303a. FIG. 15B illustrates the diamond anvils pressed into the gasket's indentations, and the diamond power 1501 thereby being pressed into and spread over the surfaces of upper gasket indentation 303a and hole 304. Diamond power 1501 prevents short circuits between gasket 302 and sample 301 (sample 301 shown in other figures) during testing.

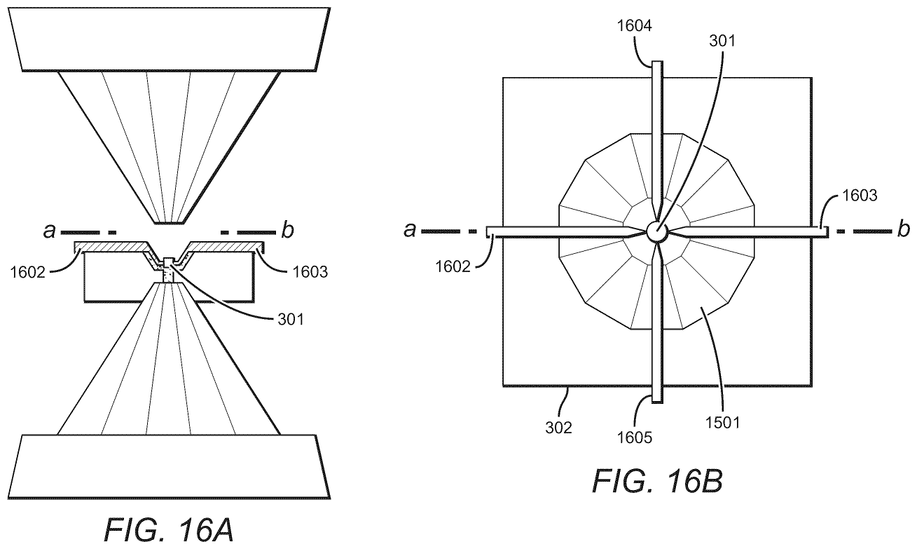

FIGS. 16A-16B illustrate a setup for obtaining resistance measurements of a sample under pressure in the DAC. FIG. 16A is an internal side view showing electrodes 1602 and 1603 placed in contact with sample 301 and extending up out of the gasket 302's top indentation. FIG. 16B is an internal top view (line a-b is shown to orient the view in FIG. 16B relative to the view of FIG. 16A) showing additional electrodes 1604 and 1605 contacting sample 301.

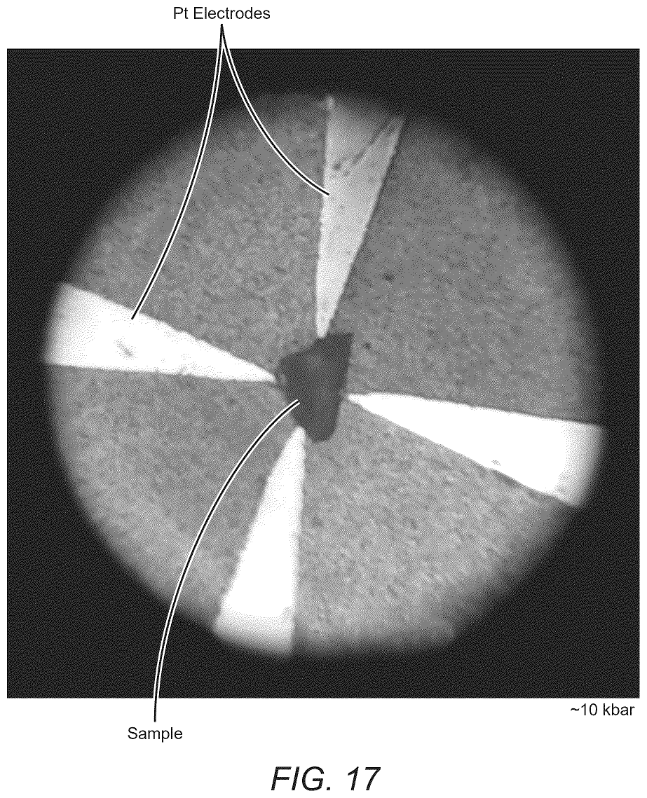

FIG. 17 is an image of an actual setup similar to that illustrated in FIG. 16B. The image shows a sample within a DAC under a pressure of about 10 kbar in contact with four platinum electrodes.

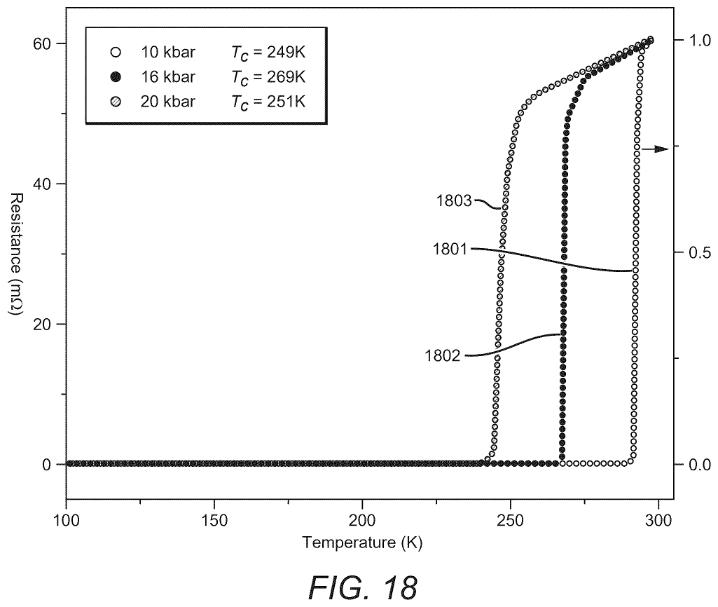

FIG. 18 presents data of resistance versus temperature for three different pressures. At each of the three different pressures, data was obtained by measuring resistance during the warming cycle to minimize the electronic and cooling noise. Line 1801 of data points (shown in blue) was obtained by measuring resistance and temperature with the sample during warming at a pressure of about 10 kbar (e.g., 10 kbar +/−0.1 kbar). Line 1802 of data points (shown in red) was obtained at a pressure of about 16 kbar. Line 1803 of data points (shown in black) was obtained at a pressure of about 20 kbar. As shown, Tc at 10 kbar was measured to be about 294K. Tc at 16 kbar was measured to be about 269K. And Tc at 20 kbar was measured to be about 251K.

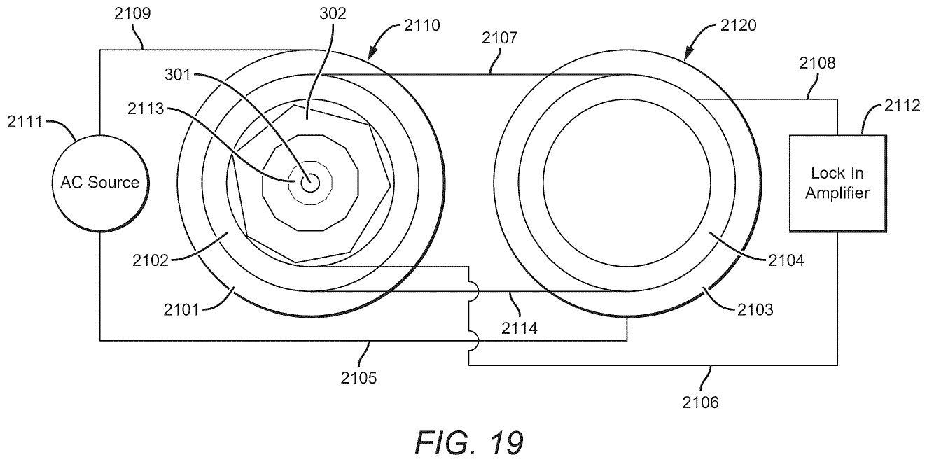

FIG. 19 illustrates an internal top view of an experimental setup for measuring magnetic susceptibility within a DAC, in accordance with one embodiment of the invention. Magnetic susceptibility measurements are used to identify the Meissner effect, an important characteristic of superconducting materials. Specifically, the characteristic refers to the expulsion of magnetic fields from a superconductor when it transitions to the superconducting state below the critical temperature. A significant, sudden drop in magnetic susceptibility signifies the transition. However, measuring magnetic susceptibility of high pressure samples within a DAC poses particular challenges because the sample size is necessarily quite small relative to a practical coil size for measuring susceptibility. Thus the relevant signals are fairly weak. The arrangement illustrated in FIG. 19 addresses this problem through use of a double coil arrangement including a primary coil around the sample and a connected “dummy coil” used to subtract out the empty volume signal from the primary coil signal as further explained below.

The setup illustrated in FIG. 19 includes primary coil 2110 and dummy coil 2120. Primary coil 2110 including two constituent coils: outer coil 2101 and inner coil 2102. Dummy coil 2120 includes also includes two constituent coils: outer coil 2103 and inner coil 2104. Outer coil 2101 of primary coil 2110 is substantially identical to outer coil 2103 of dummy coil 2120. Similarly, inner coil 2102 of primary coil 2110 is substantially identical inner coil 2104 of dummy coil 2120. In the illustrated embodiment, the coils are made by winding 42-46 gauge wires. The coils are connected in series with opposite polarity.

AC source 2111 is connected to the outer winding of primary outer coil 2101 by wire 2109 and to the outer winding of dummy outer coil 2103 by wire 2105 as shown. Lock in amplifier 2112 is connected to the inner winding of primary inner coil 2102 by wire 2106 and to the outer winding of dummy inner coil 2104 by wire 2108 as shown. The inner winding of primary outer coil 2101 is connected to the inner winding of dummy inner coil by wire 2107 as shown. And the outer winding of primary inner coil 2102 is connected to the inner winding of dummy inner coil 2104 by wire 2114 as shown.

Gasket 302 is cut down to a size that allows it to fit inside of primary inner coil 2102. Sample 301 is placed within gasket 302 and, in the illustrated embodiment, salt (NaCl) 2113 is used as a pressure medium.

Because the primary and dummy coils are identical (or substantially identical), the illustrated arrangement allows the non-sample portion of the volume inside the pickup coil (i.e., inside primary inner coil 2102) to be subtracted out, thus dramatically reducing the background signal. This allows better measurement of changes in magnetic susceptibility of the sample.

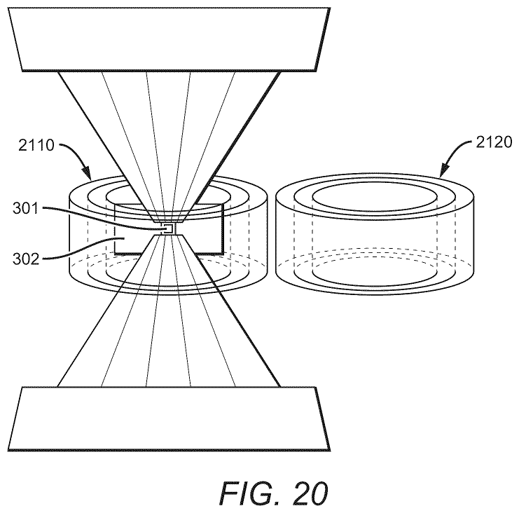

FIG. 20 shows a side view of the same setup shown in FIG. 19. Primary coil 2110 is arranged around the gasket 302 and the anvils for the DAC and dummy coil 2120 is next to primary coil 2110.

FIG. 21 is a photograph of a susceptibility measurement setup consistent with the inner top view schematic of FIG. 21. As shown, primary coil 2110 encircles diamond anvil 1401b. Dummy coil 2120 is connected in series with primary coil 2110 and with opposite polarity.

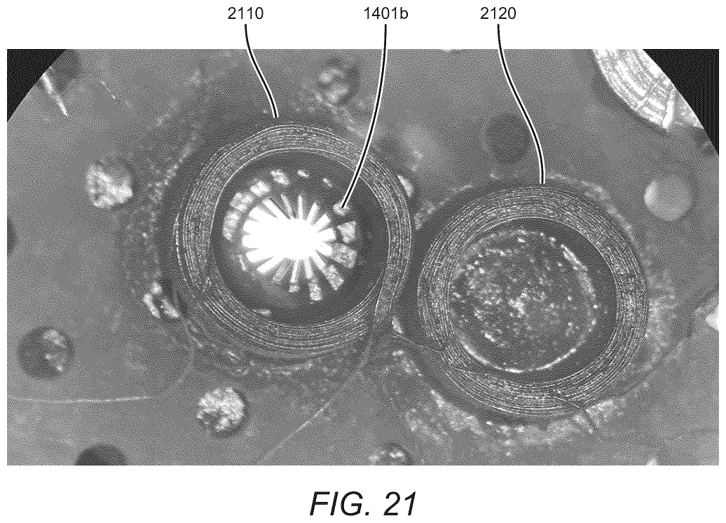

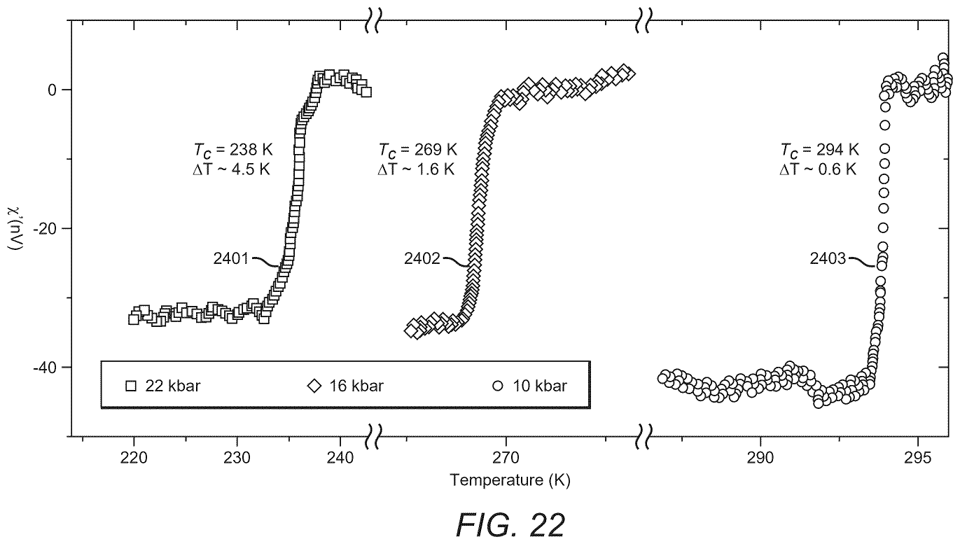

FIG. 22 presents data showing the real part of A.C. magnetic susceptibility (c′) in nanovolts (nV) versus temperature at three different pressures. The susceptibility versus temperature measurements were taken during the warming cycle. Line 2401 of data points (shown in purple) was obtained by measuring magnetic susceptibility and temperature with the sample at a pressure of about 22 kbar. Line 2402 of data points (shown in red) was obtained at a pressure of about 16 kbar. Line 2403 of data points (shown in blue) was obtained at a pressure of about 10 kbar. As shown, Tc at 22 kbar was measured to be about 238 K with a transition width (ΔT) of about 4.5 K. Tc at 16 kbar was measured to be about 269 K with a transition width of about 1.6 K. And Tc at 10 kbar was measured to be about 294 K with a transition width of about 0.6 K. These measurements show close agreement with the critical temperatures identified using resistance measurements as discussed above.

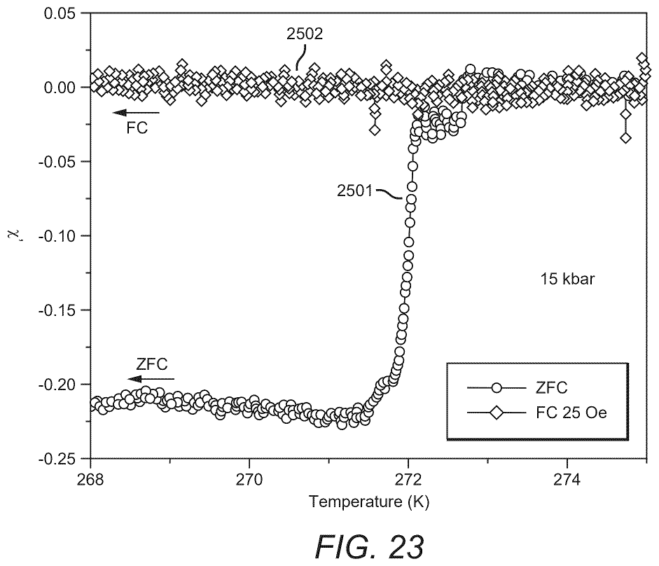

FIG. 23 presents data showing the magnetic susceptibility (c′=M/H, where M is magnetization and H is magnetic field) of the sample as a function of temperature, under conditions of zero field cooling (ZFC) and field cooling (FC) at 25 Oe. Line 2501 (red) of data points shows data obtained with zero field cooling (ZFC). Line 2502 (blue) of data points shows data obtain with field cooling (FC). The critical temperature is about 272 K.

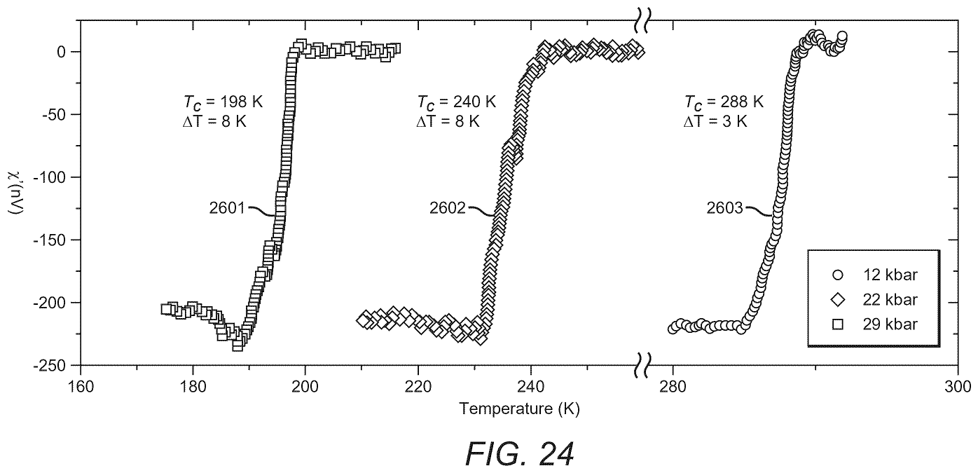

FIG. 24 shows another example of susceptibility versus temperature data obtained at various pressures. Line 2601 of data points (shown in green) was obtained by measuring magnetic susceptibility and temperature with the sample at a pressure of about 29 kbar. Line 2601 of data points (shown in blue) was obtained at a pressure of about 22 kbar. Line 2603 of data points (shown in red) was obtained at a pressure of about 12 kbar. As shown, Tc at 29 kbar was measured to be about 198 K with a transition width (ΔT) of about 8 K. Tc at 22 kbar was measured to be about 240 K with a transition width of about 8 K. And Tc at 12 kbar was measured to be about 288 K with a transition width of about 3 K. The drops in susceptibility evidencing diamagnetic shielding characteristic of the transition to superconductivity are significantly larger than those shown in FIG. 23 due to larger sample size.

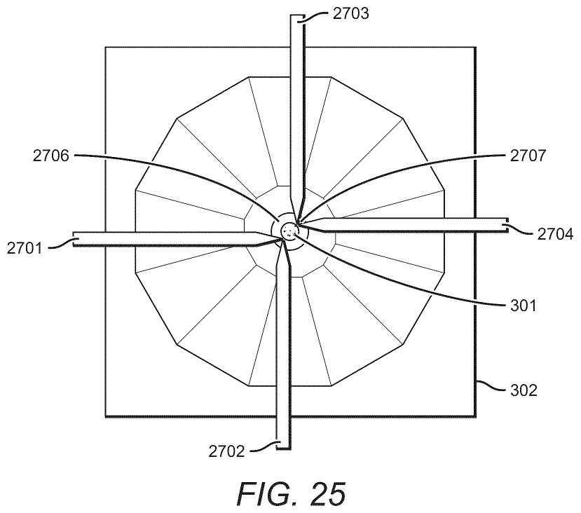

FIG. 25 illustrates an internal top view of an experimental setup for measuring heat capacity within a DAC, in accordance with one embodiment of the invention. The specific heat (C) is an important thermodynamic quality and provides a significant tool for identifying superconductive behavior. It is extensively used for confirming bulk superconductivity. Under the BCS model, superconductors have an energy gap associated with the formation of Cooper pairs, resulting in a spike in the specific heat of a superconductor at the transition temperature Tc. In the past and presently, heat capacity measurement of samples under pressure has generally been done in piston-cylinder clamp cells using well-known AC calorimetric techniques. However, piston-cylinder clamp cells have pressure limits. Therefore, it is desirable to be able to measure heat capacity in a DAC. Yet detecting heat capacity to identify this spike at high pressure in a DAC is challenging due in part to the thermal conductivity of the diamond anvils.

Continuing with the description of FIG. 25, the illustrated experimental setup implements a modified version of the typical AC calorimetric technique for measuring heat capacity. This modified technique enables sufficiently accurate heat capacity measurements in a DAC at high pressure. Specifically, as shown in FIG. 25, metal heating elements 2701 and 2702 are shorted and placed in contact with one end of a sample 301 within a gasket 302 that has been prepared as previously described. Metal heating elements 2701 and 2702 are, in some embodiments, made of either titanium (Ti), platinum (Pt), or nichrome. A thermocouple metal pair including metal 2703 and metal 2704 form thermocouple junction 2707 which is placed in contact with the other side of sample 301 across from the heating elements. In an embodiment, one thermocouple metal (2703 or 2704) is made of chromel and the other is made of alumel. Salt (NaCl) 2706 is placed around sample 301 to provide heat insulation, as well as providing a pressure transmission medium. Insulating the sample from the diamond during heating allows for more accurate measurements.

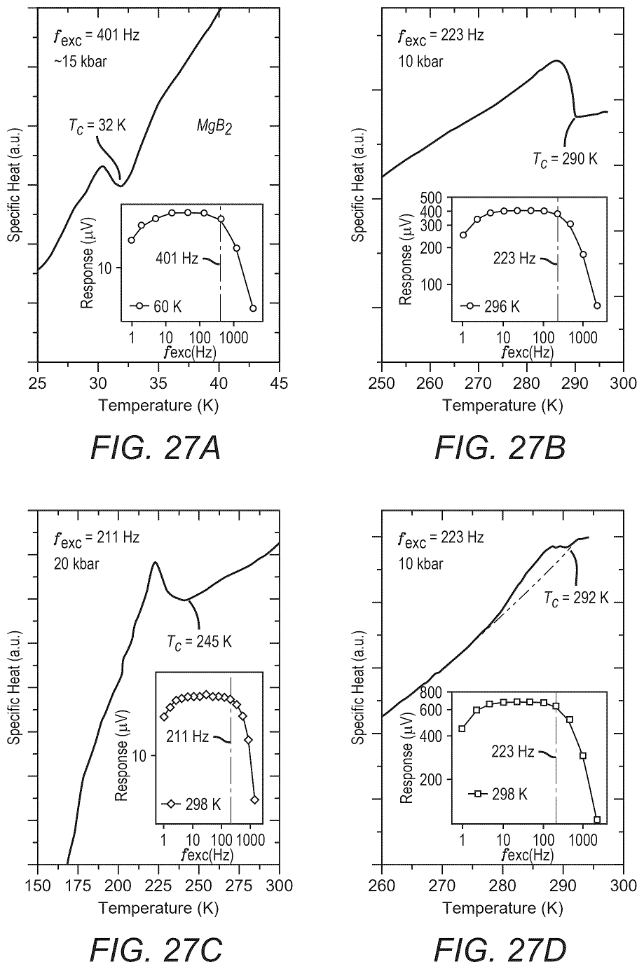

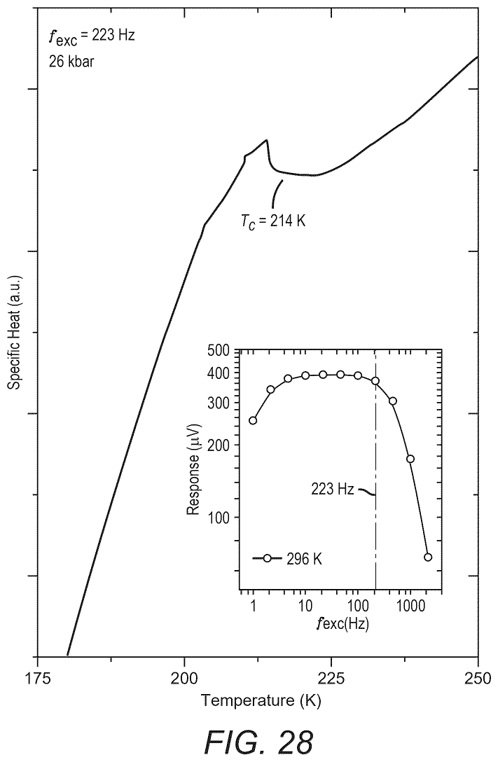

Heating elements 2701 and 2702 are connected to an AC current source (not separately shown) and thermocouple metals 2703 and 2704 are connected to a lock-in amplifier. The driving frequency of the AC source is ω/2 which results in a heat power frequency ω. The heat frequency ω should be carefully chosen. The relationship between voltage response measured at the amplifier and heat power frequency typically has a characteristic shape corresponding to three regions as the heating drive frequency ω increases. The first region (“region I”), at low ω, shows the response increasing with increasing frequency. The second region (“region II”) shows a fairly constant response as drive frequency increases. The third region (“region III”) shows a falling response as drive frequency continues to increase due to the sample not being able to thermalize fast enough to keep up with the drive frequency. Preferably, ω should be chosen to be at or near the border between region II and region III. A frequency sweep is done prior to conducting specific heat measurements in order to identify a preferred heating power frequency for measuring the material (see insets of FIGS. 27A-27D and FIG. 28).

In an embodiment, when the drive current is too high and creates a sizable DC offset, the offset can be measured by modifying the setup as a pseudo 4-probe electrical resistance and rerunning the experiment to measure resistance relative to temperature. Specifically, one of the heating elements, for example, element 2702, and one of the thermocouple metals, for example, metal 2704, can be connected to a current source while the other heating element 2701 and thermocouple metal 2703 are connected to a lock in amplifier. The resulting resistance versus temperature can be used to identify the DC offset, allowing recovery of more accurate heat capacity data from the original AC calorimetry measurements.

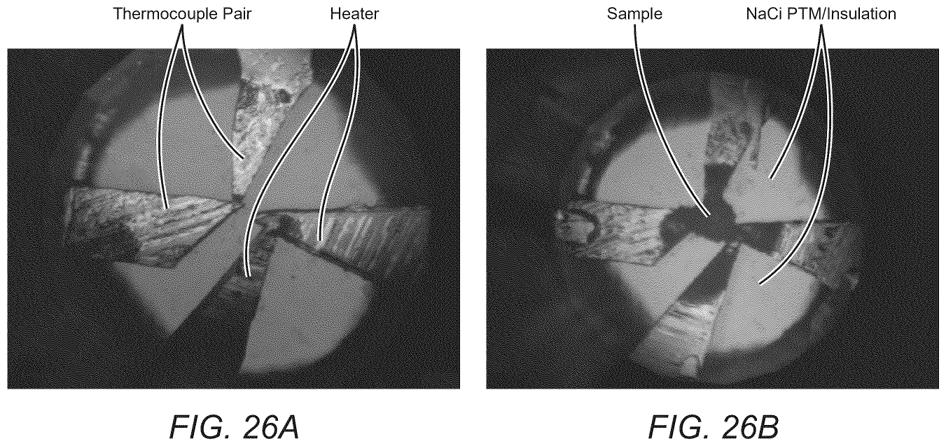

FIGS. 26A and 26B are images of an actual setup corresponding to the schematic illustration of FIG. 25. FIG. 26A shows the setup prior to adding the sample and the salt insulation. FIG. 26B shows the setup with the sample and the salt insulation added.

FIGS. 27A-28D show specific heat measurements versus temperature at various pressures using the experimental setup described above. The insets of each figure show the frequency sweeps done to identify the preferred drive frequency for the specific heat measurements. The resulting preferred drive frequencies are also shown.

FIG. 27A shows data from a run measuring magnesium diboride (MgB₂), a known superconductor at low temperatures. The measurement of MgB₂ at about 15 kbar was used to validate the experimental setup and demonstrated accurate measurement of MgB₂'s critical temperature of 32 K.

FIGS. 27B, 27C, and 27D show data measuring LuH_{3-d}Nₑ. FIGS. 27B and 27D show measurements taken at 10 kbar. The difference in the data is due to difference in sample volume, although the spike corresponding to Tc is observable from both data sets at nearly the same temperature (290 K in FIG. 27B and 292 K in FIG. 27D.) FIG. 27C shows measurements taken at 20 kbar.

FIG. 28 shows specific heat measurements versus temperature of LuH_{3-d}Nₑ taken at 26 kbar. The inset shows the frequency sweep done in advance to identify the preferred drive frequency.

### Explanation for Low Pressure/High Pressure Superconducting Embodiments

The reasons underlying the ability of the material embodiments disclosed herein to superconduct at relatively low pressures and high temperatures can potentially help one skilled in the art to identify various superconducting compounds in a range of compounds consistent with the embodiments of the invention disclosed herein. Prior to the present invention, high-temperature superconductors required extremely high pressures to achieve favorable crystal structure, which has high electron density of states at the Fermi level. However, the inventor believes that the materials disclosed herein suppress phonon softening and enhance electron-phonon coupling at relatively low pressures as a result of high electron density in the metal-hydrogen and metal-dopant bonds forming the stable lattice structure with high electron phonon coupling.

To the extent that many or even all of the 4f electrons in the metal (e.g., Lu, Tm, Yb) of the metal hydrides (including ternary metal hydrides doped with lightweight atoms such as, for example, nitrogen or boron atoms) disclosed herein become valence electrons, this could explain suppressed phonon softening and enhanced electron-phonon coupling. Also, the strong bonds formed by a dopant such as nitrogen strengthen the overall lattice structure further. This can allow for higher frequency phonons and greater material stability at lower pressures.

In view of this, one skilled in the art will appreciate that other ternary metal hydrides can potentially form high temperature/low pressure superconducting materials consistent with embodiments of the present invention.

The invention described in this specification may be embodied in many different forms and should not be construed as limited to the embodiments set forth herein. Rather, these embodiments are provided so that this specification is thorough and complete, and fully conveys the scope of the invention to those skilled in the art. Among other things, this specification may be embodied as methods or devices. While the present invention has been particularly described with respect to the illustrated embodiments, it will be appreciated that various alterations, modifications, and adaptations may be made based on the present disclosure and are intended to be within the scope of the present invention. While the invention has been described in connection with what are presently considered to be the most practical and preferred embodiments, it is to be understood that the present invention is not limited to the disclosed embodiments but, on the contrary, is intended to cover various modifications and equivalent arrangements included within the scope of the underlying principles of the invention as described by the various embodiments referenced above and below.

What is claimed is:

1. A composition of matter exhibiting superconductivity with a critical temperature (Tc) above 250 Kelvin (K) at a pressure at or below 10 kilobar, the composition of matter comprising:
a rare earth element (Ln);
a dopant (D); and
hydrogen (H).

2. The composition of matter of claim 1 wherein Ln is selected from the group consisting of lutetium (Lu), ytterbium (Yb), and thulium (Tm).

3. The composition of matter of claim 1 wherein the dopant D is selected from the group consisting of nitrogen (N) and boron (B).

4. The composition of matter of any of claims 1-3 wherein the rare earth element is Lu.

5. The composition of matter of any of claims 1-4 wherein D is nitrogen.

6. The composition of matter of any of claims 1-4 wherein D is boron.

7. The composition of matter of any of claims 1-6 characterized by a superconducting critical temperature (Tc) higher than 250 kelvin (K) when under a pressure of about 3-10 kilobar (kbar).

8. The composition of matter of any of claims 1-7 characterized by a superconducting critical temperature (Tc) higher than 290° K when under a pressure of about 7-10 kbar.

9. The composition of matter of any of claims 1-6 characterized by a superconducting critical temperature (Tc) higher than 290° K at typical room pressure, such as at or about 1 atmosphere.

10. The composition of matter of any of claims 1-9 comprising LnH_{b-δ}D_{ε} wherein δ and ε are each less than 1 and b is selected from the group consisting of 3, 4, 6, 9, and 10.

11. The composition of matter of claim 10 wherein 0≤δ≤0.5 and 0≤ε≤0.3.

12. The composition of matter of any of claims 1-11 comprising LnH_{3-δ}D_{ε}

13. The composition of matter of any of claims 1-12 comprising LnH_{2.7}D_{0.1}.

14. The composition of matter of any of claims 10-13 wherein D is nitrogen (N).

15. The composition of matter of any of claims 10-13 wherein D is boron (B).

16. The composition of matter of any of claims 1-15 wherein the rare earth element is Lu.

17. The composition of matter of any of claims 1-15 wherein the rare earth element is Tm.

18. The composition of matter of any of claims 1-15 wherein the rare earth element is Yb.

19. A process for making a superconducting composition of matter, the process comprising:
obtaining a material that exhibits superconductivity at a first temperature above 250 K and at a first pressure;
applying the first pressure to the obtained material;
lowering the temperature of the material to a second temperature that is significantly below the first temperature while maintaining the first pressure:
releasing pressure until the material is at a second pressure at which the material will be used, the second pressure being significantly lower than the first pressure; and
raising the temperature of the material to a temperature that is equal to or greater than the first temperature.

20. The processes of claim 19 wherein the obtained material comprises the composition of matter according to any of claims 1-18.

21. The process of any of claims 19-20 wherein the first pressure is in a range of about 3-20 kbar.

22. The process of any of claims 19-20 wherein the first pressure is in a range of about 3-10 kbar.

23. The process of any of claims 19-20 wherein the first pressure is in a range of about 8-12 kbar.

23. The process of any of claims 19-20 wherein the first pressure is about 10 kbar.

24. The process of any of claims 19-23 wherein the second pressure is in a range of about 1 kbar to typical ambient room pressure, e.g., about 1.01325 bar.

25. The process of any of claims 19-24 wherein the second pressure at or close to typical ambient room pressure, e.g., at or close to about 1.01325 bar.

26. The process of any of claims 19-25 wherein the second temperature is below 100 kelvin (K).

27. The process of any of claims 19-26 wherein the second temperature is below 50 K.

28. The process of any of claims 19-27 wherein the second temperature is below 30 K.

29. The process of any of claims 19-28 wherein the second temperature is about 20 K.

30. The process of matter of any of claims 19-28 wherein the second temperature is in a range of about 20 K to 4 K.

31. A composition of matter made by a process according to any of claims 19-30.

32. The composition of matter of claim 31 comprising LnH_{b-δ}D_{ε} wherein δ and ε are each less than 1 and b is selected from the group consisting of 3, 4, 6, 9, and 10.

33. The composition of matter of claim 32 wherein 0≤δ≤0.5 and 0≤ε<0.3.

34. The composition of matter of any of claims 32-33 comprising LnH_{3-δ}D_{ε}

35. The composition of matter of any of claims 32-34 comprising LnH_{2.7}D_{0.1}.

36. The composition of matter of any of claims 32-35 wherein D is nitrogen (N).

37. The composition of matter of any of claims 32-35 wherein D is boron (B).

38. The composition of matter of any of claims 32-37 wherein the rare earth element is Lu.

39. The composition of matter of any of claims 32-37 wherein the rare earth element is Tm.

40. The composition of matter of any of claims 32-37 wherein the rare earth element is Yb.

41. A method comprising using the composition of matter of any of claim 1-18 or 31-40 as a substrate to grow additional superconducting material using chemical vapor deposition, atomic layer deposition, or molecular beam epitaxy.

42. A method of making a superconducting material comprising:
mixing a rare earth metal (Ln), hydrogen and a dopant (D) under pressure in a chamber;
slowly heating the mixture in the chamber to a reaction temperature;
allowing the mixture to react at the reaction temperature and at a first pressure for a time period until an fcc material is formed; and
pressurizing the fcc material to a second pressure higher than the first pressure.

43. The method of claim 42 wherein Ln is selected from a group consisting of a rare earth element (Ln) selected from the group consisting of lutetium (Lu), ytterbium (Yb), and thulium (Tm).

44. The method of any of claims 42-43 wherein the dopant (D) is nitrogen.

45. The method of any of claims 42-44 wherein the rare earth element is Lu.

46. The method of any of claims 42-44 wherein the rare earth element is Tm.

47. The method of any of claims 42-44 wherein the rare earth element is Yb.

48. The method of any of claims 42-57 wherein the first pressure is about 4-10 megapascals (MPa).

49. The method of any of claims 42-48 wherein the reaction temperature is about 200-400 degrees Celsius (° C.).

50. The method of any of claims 42-49 wherein the time period is about 12-24 hours.

51. The method of any of claims 42-50 wherein the second pressure is about 3-20 kilobar (kbar).

52. The method of any of claims 42-50 wherein the second pressure is in a range of about 3-10 kbar.

53. The method of any of claims 42-50 wherein the second pressure is in a range of about 8-12 kbar.

54. The method of any of claims 42-50 wherein the second pressure is about 10 kbar.

55. The method of any of claims 42-54 wherein the rare earth metal, prior to reacting, has a purity of least 99%.

56. The method of any of claims 42-54 wherein the rare earth metal, prior to reacting, has a purity of least 99.9%.

57. The method of any of claims 42-54 wherein the rare earth metal, prior to reacting, has a purity of least 99.99%.

58. The method of any of claims of 42-57 wherein the ratio of hydrogen to dopant (H: D) mixed with Ln for reaction is selected from the group consisting of: at least 9:1; at least 91:9; at least 92:8; at least 93:7; at least 94:6; at least 95:5; at least 96:4; at least 97:3; at least 98:2; and at least 99:1.

59. The method of any of claims 42-58 wherein pressure is released after the first time period and before pressurizing to the second pressure higher than the first pressure.

60. A method of making a superconducting material comprising:
mixing a rare earth metal (Ln) and hydrogen under pressure in a chamber to obtain a first mixture at a first pressure;
slowly heating the first mixture in the chamber to a first reaction temperature;
allowing the first mixture to react at the first reaction temperature and at the first pressure for a first time period to obtain a rare earth metal hydride;
mixing the rare earth metal hydride with a dopant (D) to obtain a second mixture;
pressurizing the second mixture to the first pressure and slowly heating the second mixture to a second reaction temperature;
allowing the second mixture to react at the second reaction temperature for a second time period to obtain a ternary compound comprising the rare earth metal, hydrogen, and D; and
pressurizing the ternary compound to a second pressure.

61. The method of claim 60 wherein Ln is selected from a group the group consisting of lutetium (Lu), ytterbium (Yb), and thulium (Tm).

62. The method of any of claims 60-61 wherein the dopant (D) is boron.

63. The method of any of claims 60-62 wherein the rare earth element is Lu.

64. The method of any of claims 60-62 wherein the rare earth element is Tm.

65. The method of any of claims 60-62 wherein the rare earth element is Yb.

66. The method of any of claims 60-65 wherein the first pressure is 4-10 megapascals (MPa).

67. The method of any of claims 60-66 wherein the first reaction temperature is 200-400 degrees Celsius (° C.).

68. The method of any of claims 60-67 wherein the second reaction temperature is 200-500° C.

69. The method of any of claims 60-69 wherein the second pressure is about 3-20 kbar.

70. A composition of matter made by the method of any of claims 60-69.
